(19) United States
(12) Patent Application Publication
(10) Pub. No.: US 2004/0119105 A1
(43) Pub. Date: Jun. 24, 2004

(54) Ferroelectric memory

(76) Inventor: Dennis Robert Wilson, Woodland Park, CO (US)

Correspondence Address: Dale B. Halling, Suite 311, 24 South Weber Street, Colorado Springs, CO, 80903, US

(21) Appl. No.: 10/325,230

(22) Filed: Dec. 18, 2002

(51) Int. Cl. G11C 11/22

(52) U.S. Cl. 257/295

(57) ABSTRACT

A ferroelectric memory cell that is more compact and uses less power includes a word line connected to a gate of a transistor. A ferroelectric capacitor has a first plate connected to a drain of the transistor. A bit line is connected to a source of the transistor and runs perpendicular to the word line. A plate line forms a second plate of the ferroelectric capacitor. The plate line runs parallel to the bit line.

### FIELD OF THE INVENTION

The present invention relates generally to the field of semiconductor memories and more particularly to a ferroelectric memory cell and to an architectural arrangement of an array of ferroelectric memory cells.

### BACKGROUND OF THE INVENTION

Reducing the size of a semiconductor memory is a constant goal of memory designers. Size directly contributes to cost and power requirements, smaller size less cost and less power. Current configurations of ferroelectric memories are similar in design and structure to conventional DRAM memories. Ferroelectric memory cells use a ferroelectric capacitor to store information in a similar fashion to that of oxide capacitors used in DRAM's. A key difference is the data or information for a ferroelectric capacitor is contained in the orientation of the dipoles in the physical memory cell. This dipole orientation remains after the electric field is removed resulting in the non-volatile characteristics of the ferroelectric device. Applying a field across the electrodes of the ferroelectric device during writing and read/restore of the cell controls this orientation. A change in the polarity of the applied voltage changes the data state stored in the memory cell. To achieve this polarity change or reversal requires applying a positive or negative voltage to one of the electrodes of the device while maintaining the other electrode at ground or by being able to apply a positive voltage to either electrode while holding the opposite electrode at ground. One way of achieving this is to have access to both electrodes on a cell-by-cell basis or via groups of cells that share one of the electrodes of the ferroelectric capacitors in common. Just as in early DRAM's, the first ferroelectric memories utilized 2 transistors (2T) and 2 capacitors (2C) to store each bit of information referred to as 2T2C. As the stability of the ferroelectric devices has improved the ferroelectric memories have utilized a single transistor (1T) and capacitor (1C) to store each bit of information referred to as 1T1C. When a single transistor and single capacitor are used to store data a reference cell is used in conjunction with the memory cell to determine the data state for a “1” or “0”. The requirement of accessing both terminals of the ferroelectric device has resulted in an additional connection in the cell often referred to as a plate line. A single transistor single capacitor ferroelectric memories cell utilizes a bit line, word line and plate line. Although DRAM's also have a plate line the typical advanced DRAM shares this plate line over the entire array or very large sections of sub arrays. Also in the DRAM case the common plate line can remain at a fixed potential, typically VCC/2 or power supply voltage divided by one half. For the ferroelectric memory the plate line must be driven to a positive supply voltage and also to ground to both read and restore or write the data into the ferroelectric cell. The requirement of driving the plate line and having access to both electrodes of the ferroelectric memory cell has been a major reason why ferroelectric memories have not achieved the density and hence lower cost of DRAM memories.

The common plate line used in the ferroelectric memories can represent a sizable capacitive load to drive during memory operation and therefore the size or number of cells connected to an individual plate line must be carefully chosen to balance the performance, power and current transient requirements of the particular memory design. To date most approaches have shared the plate on either a word line by word line basis or a plate line per pair of word lines. This approach places the circuitry necessary to drive the plate line in the same pitch or physical direction as the circuitry required to drive the word lines. This physical structure then sets the aspect ratio of the memory cell. For the approach where the plate line is parallel to the word line, often referred to as word plate parallel, the “Y” pitch or row pitch is wide and the bit or column or X pitch is narrow. The added plate lines also increase the complexity of the peripheral driver circuitry especially those required to drive the memory array plate lines. Typically the drivers for the plate lines consume a large portion of the memory array area and contribute to a less efficient and larger memory core further increasing costs and design complexity.

This aspect ratio for ferroelectric memory cells is opposite that of conventional DRAM's where the typically x-y pitch or aspect ration is reversed. For a DRAM the X or bit pitch is wide and the Y or word pitch is narrow. This has an advantage in that the typical sensing circuit in a DRAM is a cross-coupled balanced latch. The DRAM aspect ratio allows for more room for the sense amplifier layout improving overall circuit margins. The typical row or word driver can be more easily drawn in the narrow Y pitch of a DRAM. Therefore there exists a need for not only a more compact ferroelectric memory cell to compete with the size of the DRAM memory cell and provide reduce costs but also a ferroelectric memory cell where the extra spacing required for the individual plate lines or plate wires does not compromise the overall x-y pitch or aspect ratio of the memory cell. Additionally a cell layout that has a larger X or column pitch would increase the space available for the sense amplifier layout resulting in a design more like that of the proven DRAM approach for high margin sensing schemes.

Most conventional large memories utilize a folded bit line approach in the array configuration for sensing of the individual memory cell data. This configuration uses bit lines in pairs with true complement data on each pair of bit lines. In a one transistor one capacitor memory one line of the bit line pair would contain the cell information and the other bit line of the pair would contain the reference cell information. Typically the data state of the bit lines is sensed with a cross coupled latch sense amplifier. Generally signal levels available for the sensing are very small and require highly sensitive amplifiers for reliable operation. These very small signals are susceptible to noise from various sources. One noise source is the capacitive coupling from one bit line to another through various fringing fields that are created via the physical proximity and layout of the bit line wires. In typical operation of a ferroelectric memory cell the plate line is pulsed to read the ferroelectric memory cell prior to sensing. The movement of this plate line can create significant amounts of noise in the memory resulting from the capacitive coupling between the bit lines and plate line. In a word bit line parallel approach the plate line runs perpendicular to the bit lines and generally the noise is coupled common mode or equally to each bit line pair. For a memory cell layout where the plate line is parallel to the bit lines significant amounts of differential noise coupling can be generated between the plate line and the individual bit line pairs.

In a one transistor one capacitor memory cell where a reference cell is used in conjunction with the memory cell for determining the data state for a “1” or “0”, the reference cell or cells are placed at one end of the memory array. Typical also in a one transistor one capacitor the bit lines are twisted at various point in the array to neutralize cumulative capacitive coupling effects that occur do to the close proximity of the bit line conductors. These bit twists create the need for multiple rows references to accommodate the twists. In a typical memory array there are generally 4 bit line segments or sub sections in the column direction to accommodate the bit twist to cancel bit line to bit line noise coupling. This configuration creates the need for 4 reference rows for each of the bit line sub sections. These four reference rows are usually placed or grouped physically at one end of the array. This physical separation makes it difficult to share the common plate line between memory cells and reference cells and requires more complicated timing for sensing.

Further the power associated with memories of this type is directly related to the overall cell size and in particular with ferroelectric memories the power is also related to the size and number of plate drivers required. The smaller the memory cell and the fewer and smaller the number of plate drivers the less the overall power consumption of the memory.

It is the object of the current invention to present a solution that achieves a reduction in the memory cell size, changes the aspect ration of the memory cell consistent with achieving a wider bit or X pitch and a narrower Y or row pitch to improve the layout of the sense amplifier region and the word drivers, to provide a distributed reference scheme that allows sharing of a common plate line between memory cells and reference cells reducing the timing and operation complexity of the sensing without compromising the sensing margin, minimizes the overall layout area associated with the plate driver circuitry and provides a balanced memory cell layout to eliminate the potential noise imbalance created by a plate lines parallel to bit lines.

### BRIEF DESCRIPTION OF THE DRAWINGS

FIG. 1 is a layout of a plurality of ferroelectric memory cells in accordance with one embodiment of the invention;

FIG. 2 is a cross section taken along a line A-A of the plurality of ferroelectric memory cells of FIG. 1 in accordance with one embodiment of the invention;

FIG. 3 is a layout of a plurality of ferroelectric memory cells in accordance with one embodiment of the invention;

FIG. 4 is a cross section taken along a line B-B of the plurality of ferroelectric memory cells of FIG. 3 in accordance with one embodiment of the invention;

FIG. 5 is a schematic diagram of a plurality of ferroelectric memory cells of FIG. 1 in accordance with one embodiment of the invention;

FIG. 6 is a schematic diagram of a plurality of ferroelectric memory cells of FIG. 3 in accordance with one embodiment of the invention;

FIG. 7 is a block diagram of a memory core in accordance with one embodiment of the invention;

FIG. 8 is a block diagram of a memory core in accordance with one embodiment of the invention;

FIG. 9 is a block diagram of a portion of a memory core in accordance with one embodiment of the invention;

FIG. 10 is a schematic diagram of a sub-bit twist in a memory core in accordance with one embodiment of the invention;

FIG. 11 is a more detailed topological diagram of a portion of the sub-bit twists and plate line of a memory core in accordance with one embodiment of the invention;

FIG. 12 is a schematic diagram of a bit twist in a memory core in accordance with one embodiment of the invention;

FIG. 13 is a schematic diagram of a plurality of plate drivers and plate wires in accordance with one embodiment of the invention;

FIG. 14 is a schematic diagram of plurality of reference cells in accordance with one embodiment of the invention;

FIG. 15 is a schematic diagram of a portion of two columns of the memory core showing memory cells reference memory cells and sub-bit twists in accordance with one embodiment of the invention;

FIG. 16 is a schematic diagram of a word line decoder and driver in accordance with one embodiment of the invention;

FIG. 17 is a schematic diagram of a portion of a reference word line driver in accordance with one embodiment of the invention;

FIG. 18 is a schematic diagram of a portion of a plate driver in accordance with one embodiment of the invention;

FIG. 19 is a block diagram of a portion of a memory core showing the placement of the word line, plate line and reference word line drivers and decoders in accordance with one embodiment of the invention;

FIG. 20 is a schematic diagram of a reference word line and plate line decoder including a reference word line driver block and plate line driver block in accordance with one embodiment of the invention; and

FIG. 21 is a timing diagram showing the electrical signals and their timing relationships for operation of the memory cell, reference memory cell and word line, reference word line and plate line drivers and decoders.

### DETAILED DESCRIPTION OF THE DRAWINGS

A ferroelectric memory cell that is more compact and orients the plate line to be parallel to the bit lines includes a word line connected to a gate of a transistor. A ferroelectric capacitor has a first plate connected to a drain of the transistor. A bit line is connected to a source of the transistor and runs perpendicular to the word line. A plate line forms a second plate of the ferroelectric capacitor. The plate line runs parallel to the bit line. In one embodiment, the plate line is shared by two memory cells. This significantly reduces the size of a memory cell.

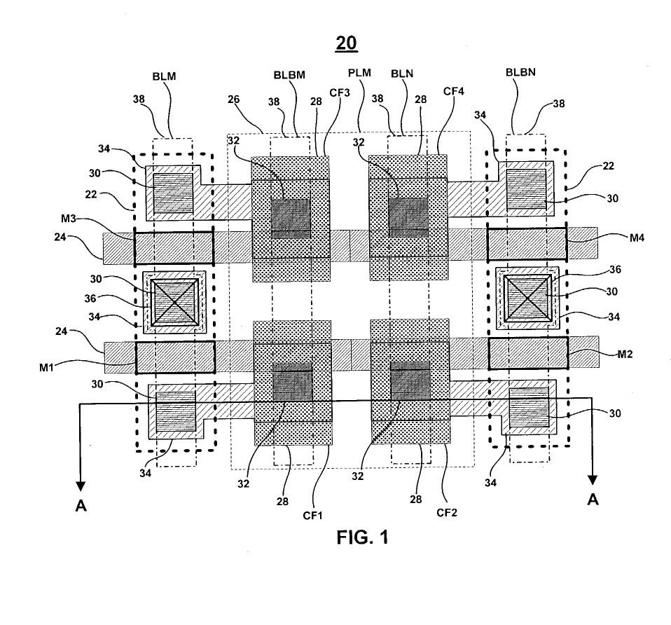

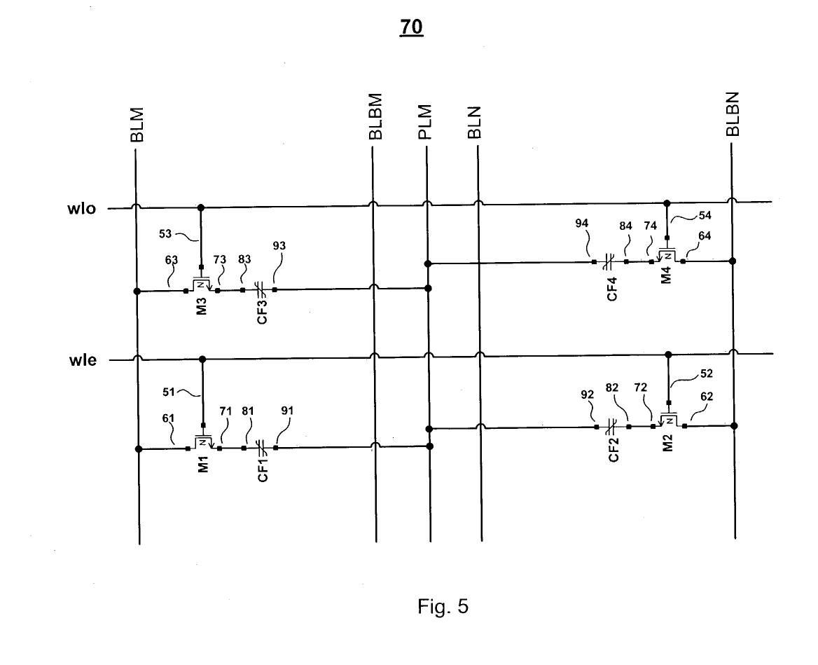

FIG. 1 is a layout 20 of a plurality of ferroelectric memory cells in accordance with one embodiment of the invention. In particular FIG. 1 shows a layout of 4 memory cells in accordance with one embodiment of the present invention. The layout of FIG. 1 corresponding to the schematic diagram of FIG. 5 is comprised of multiple layers necessary to provide the interconnections and to form the transistors M1, M2, M3, M4 and ferroelectric capacitors CF1, CF2, CF3, CF4 illustrated in the schematic diagram of FIG. 5. The transistors M1, M2, M3 and M4 outlined by a thick square are formed at the intersection of the active area layer 22 shown as a thick dashed line and the polysilicon layer 24 shown with a dense fill diagonal line pattern. The ferroelectric capacitors are defined at the intersection of the bottom electrode layer 26 shown as a thin dashed line and the top electrode layer 28 shown with a dot fill pattern. The common source regions of transistors M1 and M3 and of transistors M2 and M4 are connected with a contact 30 shown with a horizontal line fill pattern to a first metal 34 shown with a sparse fill diagonal line pattern. A via 36 shown as an X fill connects the first metal 34 to a second metal 38 shown with a dash-dot line. Four second metal wires, 38 are the bit line connections BLM, BLBM, BLN and BLBN respectively also shown in the corresponding schematic diagram of FIG. 5. The drains of each of the transistors M1, M2, M3 and M4 are separately connected with a contact 30 to a first metal layer 34. The first metal layer 34 is then connected to top electrode 28 through a top electrode contact 32 of the ferroelectric capacitor. Each transistor has a separate ferroelectric capacitor connected to its drain region. For example transistor M1 is connected via a contact 30, first metal 34, top electrode contact 32 to the top electrode layer of ferroelectric capacitor CF1. Similarly the other transistors are likewise connected to their corresponding ferroelectric capacitors as diagrammatically show in FIG. 5. In the layout drawing of FIG. 1 the four ferroelectric capacitors 28, labeled CF1, CF2, CF3 and CF4 share a common bottom electrode 26 labeled PLM. This common bottom electrode runs parallel to the bit lines BLM, BLBM, BLN and BLBN. The bit lines 38 are grouped in pairs in a typical memory array. Each bit line pair BLM, BLBM and BLN, BLBN have one portion of the second metal 38 pair running over top of and centered above the top electrode 28.

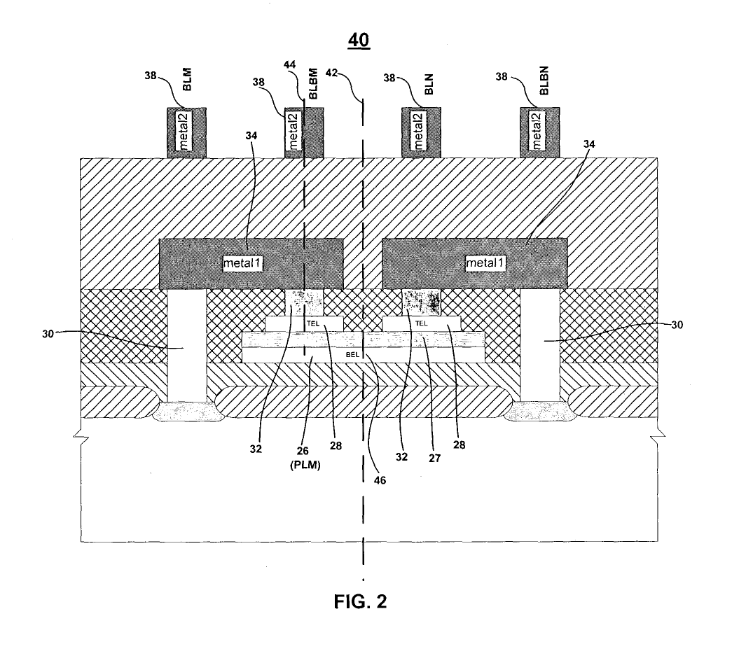

FIG. 2 is a cross section 40 taken along a line A-A of the plurality of ferroelectric memory cells of FIG. 1 in accordance with one embodiment of the invention. The cross section is through the ferroelectric capacitors formed by the top electrode layers 28 the ferroelectric material 27 and the bottom electrode 26. The cross section clearly shows that the bottom electrode 26 is shared by two ferroelectric capacitors. Note that the two memory cells are mirror images of each other around centerline 42. The common bottom electrode 26 or plate line underlies the top electrode 28, first metal 34 and one wire of each second metal 38 of each bit line pair by and equal amount on each mirrored cell around center line 42. One second metal 38 from each bit line pair BLM, BLBM and BLN, BLBN is centered over the top electrode 28 of the individual memory cells along center line 44. This centering of the second metal bit lines 38, top electrode plates 28 and symmetrical placement of the bottom electrode 26 allows for balanced capacitor coupling between the various connection elements in the ferroelectric cell.

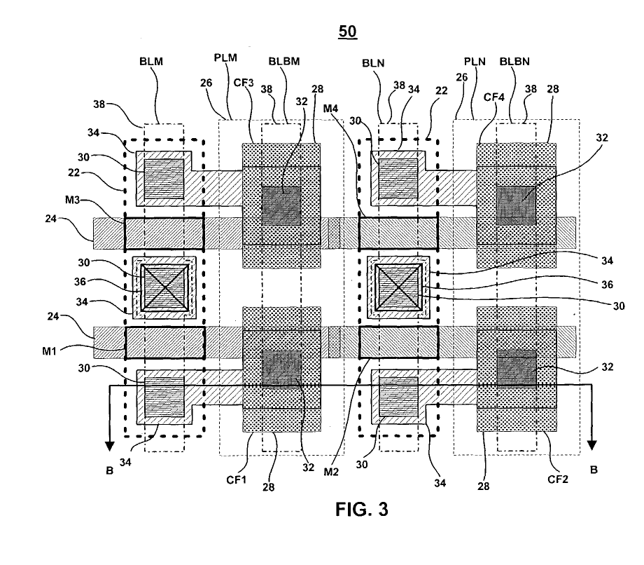

FIG. 3 is a layout 50 of a plurality of ferroelectric memory cells in accordance with one embodiment of the invention. FIG. 3 is similar to FIG. 1 and the same reference numerals are used to designate similar parts. In this embodiment, the bottom electrode 26 and ferroelectric material 27 are not shared by two capacitors.

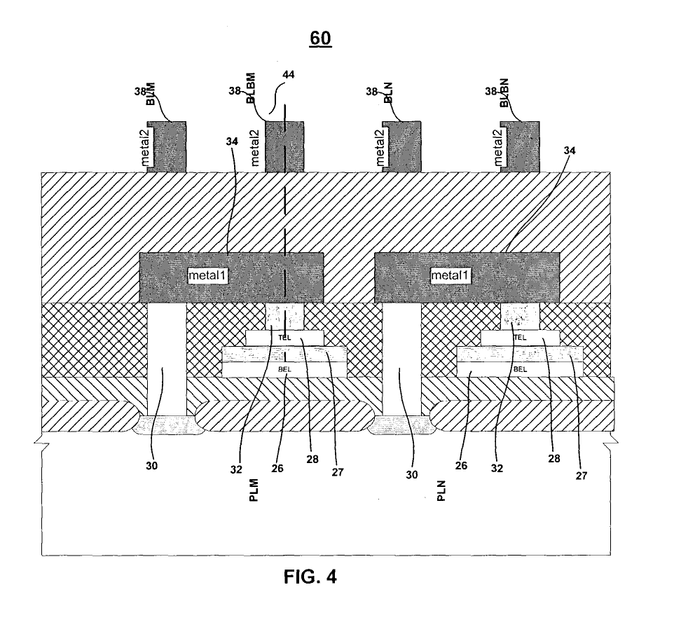

FIG. 4 is a cross section 60 taken along a line B-B of the plurality of ferroelectric memory cells of FIG. 3 in accordance with one embodiment of the invention. The cross section clearly shows two separate plate lines PLM and PLN.

FIG. 5 is a schematic diagram 70 of the plurality of ferroelectric memory cells of FIG. 1 in accordance with one embodiment of the invention. The schematic diagram 70 represents 4 memory cells that utilize a shared plate line running parallel to the bit lines. The memory cell 70 has four transistors (first transistor; second transistor; third transistor; fourth transistor) M1, M2, M3 and M4 and four capacitors (first ferroelectric capacitor, second ferroelectric capacitor, third ferroelectric capacitor, fourth ferroelectric capacitor) CF1, CF2, CF3 and CF4. A word line WLO is connected to a pair of gates (first gate, second gate ) 51, 52 of transistors M1 and M2. A second word line WLO is connected to a second pair of gates (third gate, fourth gate) 53, 54 of transistors M3 and M4. A first bit line BLM is connected to the source 61 of transistor M1 and to the source 63 of transistor M3 and runs parallel to a common plate line PLM and perpendicular to the word lines WLE and WLO. A first complimentary bit line BLBM runs parallel to a common shared plate line PLM. A second bit line BLN is connected to the source 62 of transistor M2 and to the source 64 of transistor M4. A second complimentary bit line BLBN also runs parallel to a common shared plate line PLM. Note that the bit lines BLM, BLBM, BLN and BLBM are at the same physical layer (See FIG. 2). A drain 71 of the first transistor M1 is connected to a first top electrode 81 of the first capacitor CF1. In a similar manner the drain 72 of M2 is connected to a second top electrode 82 of the second capacitor CF2, the drain 73 of M3 is connected to the top electrode 83 of CF3 and the drain 74 of M4 is connected to the top electrode 84 of CF4. A plate line PLM is connected to the bottom electrodes (first bottom electrode 91, second bottom electrode 92, third bottom electrode 93 and fourth bottom electrode 94) of capacitors CF1, CF2, CF3, and CF4 respectively. In one embodiment, the plate line PLM and the bottom electrodes 91, 92, 93 and 94 are formed by the same physical structure 26 as shown in FIG. 2. A first complementary bit line BLBM runs parallel to the plate line PLM. A second bit line BLN also runs parallel to the plate line PLM and is a mirror image of the first complementary bit line BLBM about a centerline (image line) 42 as shown in FIG. 2. Note that the plate line PLM is perpendicular to the word lines WLE and WLO. Referring to FIG. 2, it is also apparent that the bit line pairs BLM, BLBM and BLN, BLBN are symmetrically placed about a centerline (image line) 42 as shown in FIG. 2. In addition, it should now be apparent that the top electrodes 28 (FIGS. 2 & 4) are placed symmetrically on either side about the centerline 46 of the plate line 26. Finally referring to FIG. 1, the top electrodes are symmetrically placed relative to a centerline 44 of the bit lines BLBM and BLN of FIG. 5 (38 of FIG. 2). The symmetry of the memory cell equalizes the capacitance and cross talk between lines. By sharing the plate line the memory cell size is significantly reduced compared to previous memory cell architectures. A reduction of approximately 38% has been shown. The embodiments of FIGS. 1, 2, 3, 4, 5 & 6 also reduces the cell size by having the word line perpendicular to the plate line allowing closer spacing between memory cells. In addition because the X or column pitch is wider for this memory cell configuration the sense amplifier circuit layout is more efficient and more easily balanced for capacitive coupling. This improved balance reduces the noise associated with mismatched sense amplifier resulting in better sense amplifier margin.

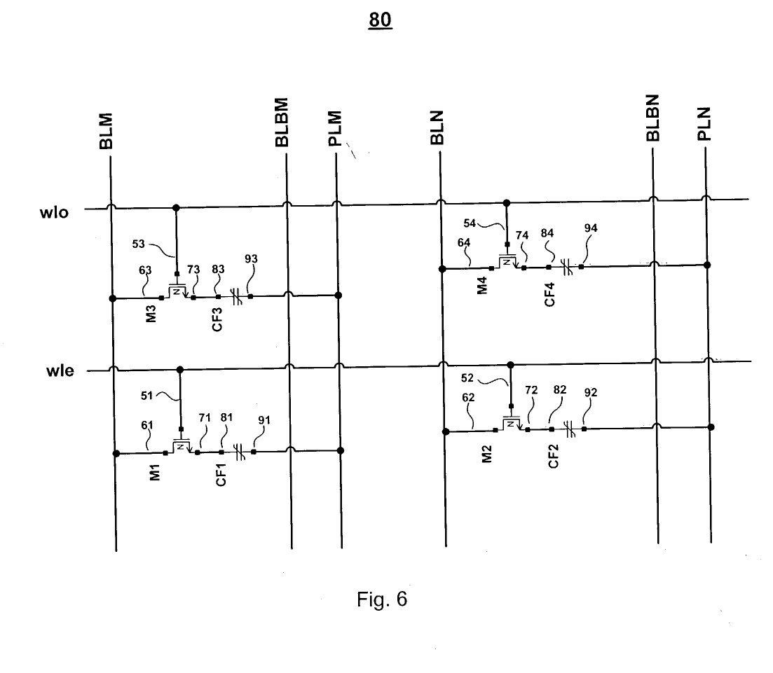

FIG. 6 is a schematic diagram 80 of the plurality of ferroelectric memory cells of FIG. 3 in accordance with one embodiment of the invention. The memory cell 80 has a word line WLE connected to a gate 51 of a transistor M1. A ferroelectric capacitor CF1 has a first plate 81 connected to a drain 71 of the transistor M1. A bit line BLM is connected to a source 61 of the transistor M1. The bit line BLM runs perpendicular to the word lines WLE and WLO. A plate line PLM is connected to a second plate 91 of the ferroelectric capacitor CF1. The plate line PLM runs parallel to the bit line BLM. A complementary bit line BLBM runs parallel to the bit line BLM. Note that the bit line BLM and the complementary bit line BLBM are at the same physical layer (See FIG. 4). The bit line BLM is not over the plate line PLM but the complementary bit line BLBM is over the plate line PLM (, the top electrode 28 and/or the intermediate metal1 34 depending on the particular cross section (See FIGS. 1,2 and 3,4). Likewise a second transistor M3 and ferroelectric capacitor CF3 are connected to bit line BLM and plate line PLM. A second complimentary bit line BLBN is connected to the drain 62 of transistors M2 and the drain 64 of transistor M4. A second plate line PLN is connected to the plate 92 of ferroelectric capacitor CF2. The second plate line, PLN is also connected to the plate 94 of ferroelectric capacitor CF4. Plate 92 of the ferroelectric capacitors CF2 is formed by the plate line PLN. Plate 94 of the ferroelectric capacitors CF4 is formed by the plate line PLN. In one embodiment, the bit line BLM is connected via a first contact and a metal layer to an intermediate metal layer and a second contact to the sources of the transistors M1 and M3. Note that the complementary bit line BLBM has a centerline 44 (see FIG. 4) and the top electrode 81 (28) and the bottom electrode PLM (26) are placed symmetrically under the centerline 44. This allows for uniform coupling and fringing fields even with misalignment.

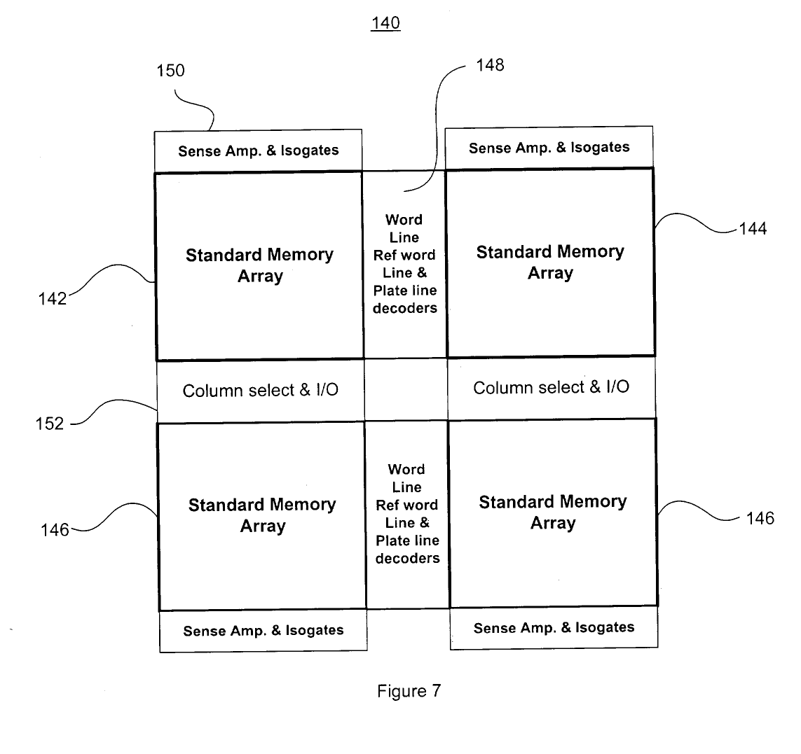

FIG. 7 is a block diagram of a memory core 140 in accordance with one embodiment of the invention. The memory core 140 includes a first pair of standard memory cell arrays 142, 144 extending in a first direction. A second pair of standard memory cell arrays 142, 146 extend in a second direction. Word line, reference word line and plate line decoders and drivers 148 are between the first pair of standard memory cell arrays 142, 144. An array of sense amplifiers 150 is located at the top of standard memory cell array 142. Other sense amplifier arrays 150 are likewise located on an outside edge of the other standard memory arrays. A column and I/O circuitry 152 is located between the second pair of standard memory cell arrays 142, 146.

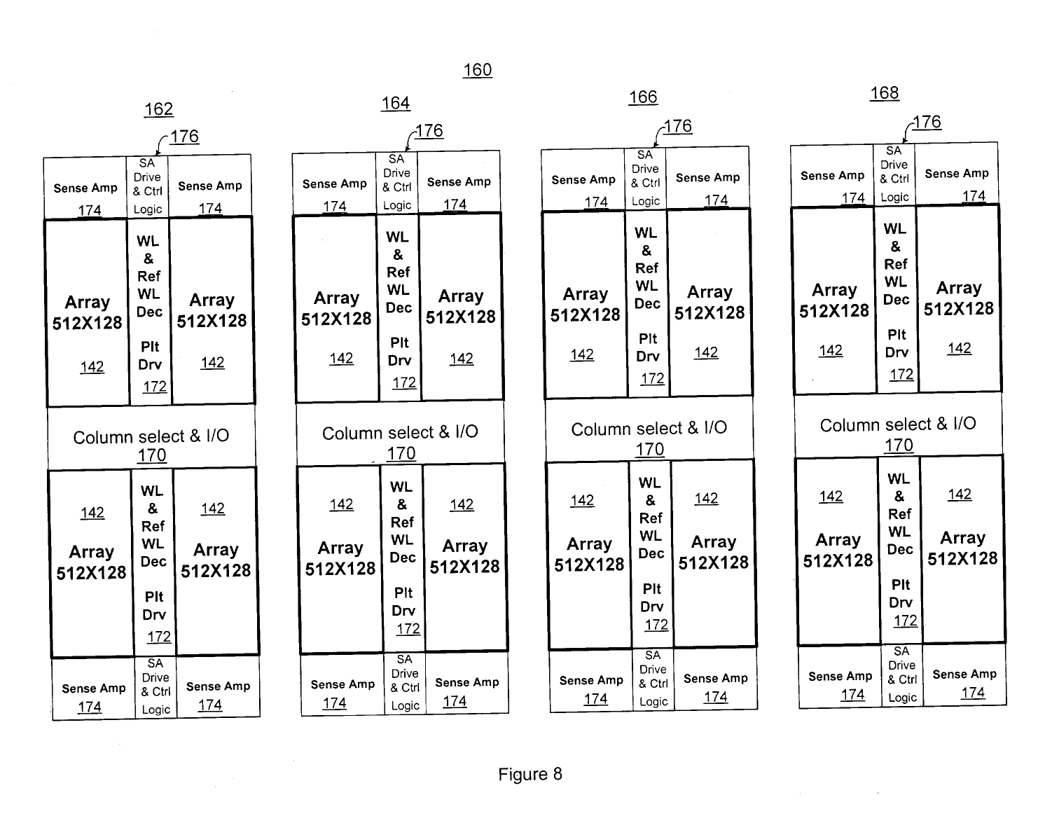

FIG. 8 is a block diagram of a memory core 160 in accordance with one embodiment of the invention. The memory core 160 has a plurality of standard memory cell arrays 142. In this embodiment, a standard memory cell array is shown as 512×128 memory cells, however the invention is not limited to a particular size standard memory cell array. The standard memory cell arrays 142 are grouped into four groups 162, 164, 166, 168 of four standard memory cell arrays. A column select and input output (I/O) data 170 are placed between pairs of memory cell arrays in the vertical direction (vertical direction here is relative to the writing on the drawing and has no other implication) in each of the groups 162, 164, 166, 168. The word decoder/driver, reference decoder/driver and plate drivers 172 are placed between every pair of standard memory cell arrays. Sense amplifiers and isolation gates 174 are placed at the top/bottom of each of the groups 162, 164, 166, 168 of standard memory cell arrays (top/bottom direction here is relative to the writing on the drawing and has no other implication). The sense amplifier drivers and control logic 176 is placed between the sense amplifiers and isolation gates 174.

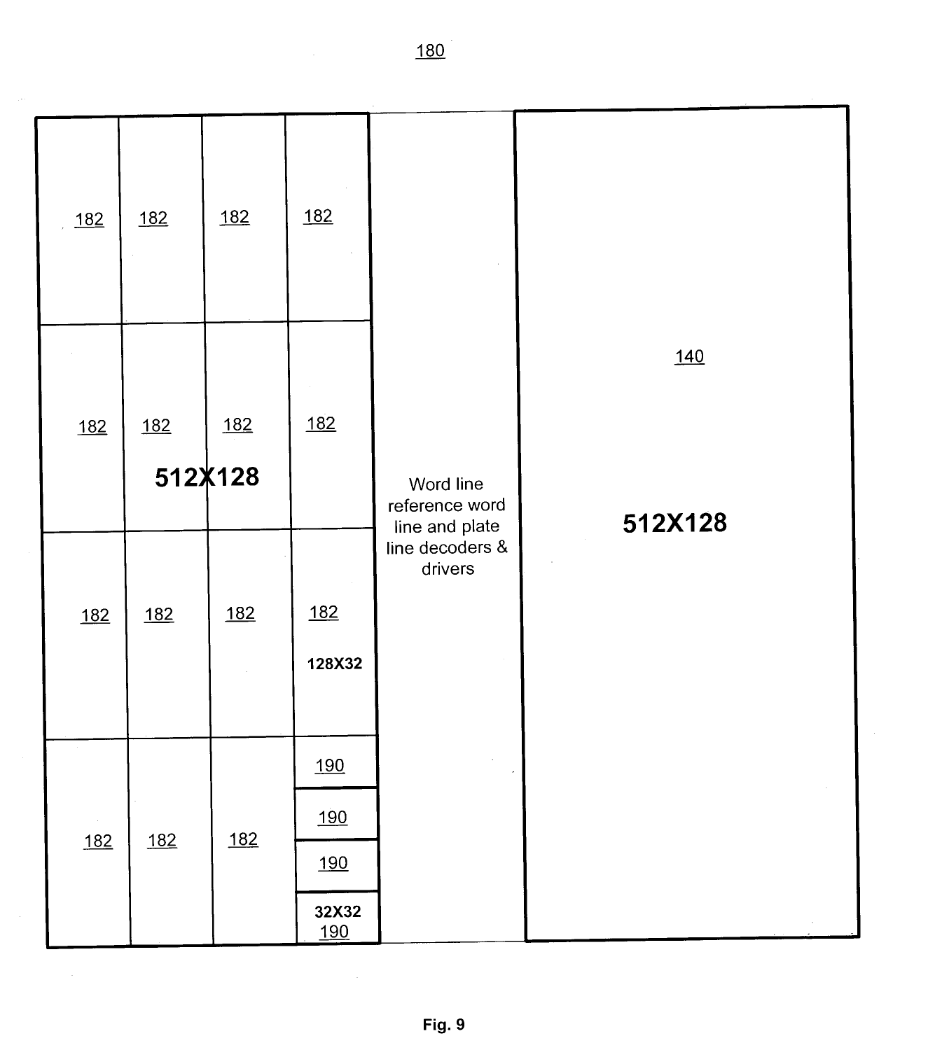

FIG. 9 is a diagram of a portion of a memory core 180 in accordance with one embodiment of the invention. The diagram shows two standard memory cell arrays 142. The standard memory cell arrays are formed by a plurality of sub-memory cell arrays 182. The sub-memory cell arrays are formed by a plurality of basic memory cell arrays 190. The basic memory cell array is shown as a 32×32 block of memory cells, however the invention is not limited to this size of basic memory cell arrays.

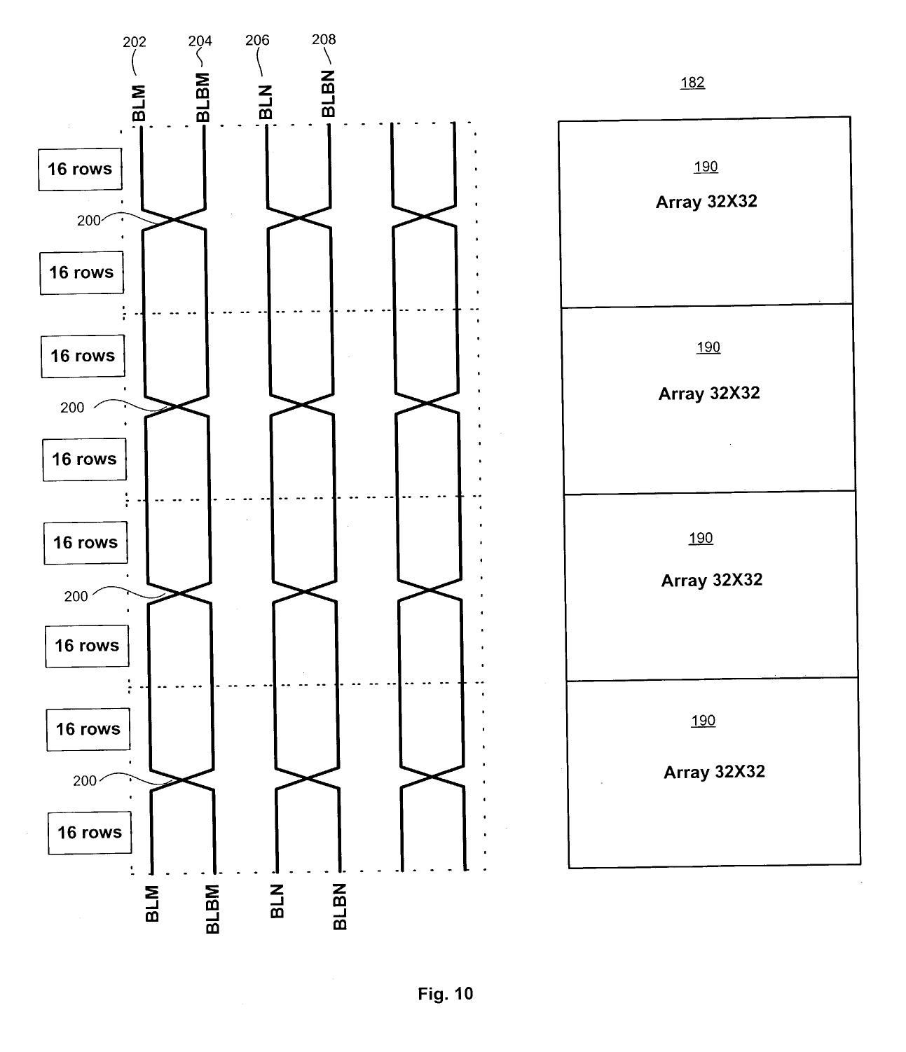

FIG. 10 is a schematic diagram of a sub-bit twist in a basic memory cell array 190 in accordance with one embodiment of the invention. The diagram shows four basic memory cell arrays 190 stacked in a line. The left side of the drawing shows the bit twist locations for three columns of memory cells. Thus the first bit line (BLM) 202 and first complementary bit line (BLBM) 204 have a bit twist 200 at the middle of a basic memory cell array 190. The sub-bit twist 200 equalize the coupling between the first bit line 202 and the second bit line 206 to the plate line 26, the top electrode 28 and/or the intermediate metal1 34 depending on the particular cross section (See FIGS. 1,2 and 3,4) This is true for all the bit lines.

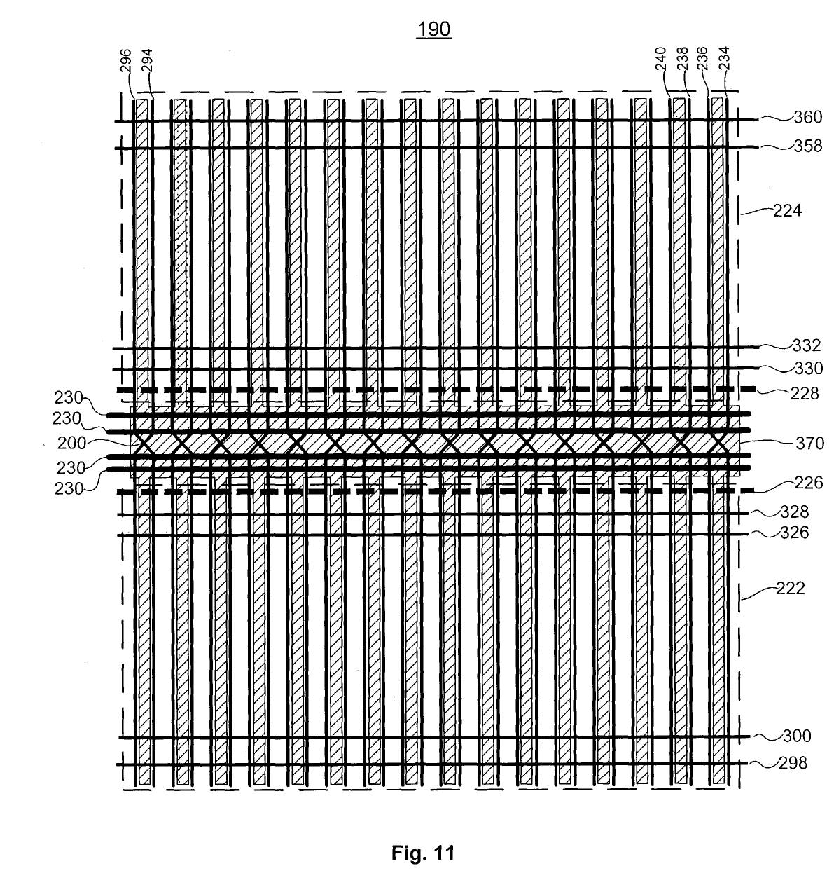

FIG. 11 is a more detailed schematic diagram of a portion of a basic memory cell array 190 in accordance with one embodiment of the invention. The basic memory cell array 190 has two parts (sub-basic memory cell array) 222, 224 of 16×32 memory cells (other sizes possible). As illustrated in sub-basic memory cell array 222, the sub-basic array is comprised of 32 bit line pairs 234, 236, 238, 240 through 294, 296, 16 words lines, 298, 300, through 326, 328 and a row of reference cells 226. The two sub-basic memory cell arrays share a common plate line 370 shown as diagonal fill. This cell illustrates a shared plate line as illustrated schematically in FIGS. 1,2 & 5. Other configurations are also possible including the separate plate lines as shown in FIGS. 3,4, & 6. The two sub-basic memory cell arrays share the plate line and bit twists 200 in the center. This configuration utilizes the shared space between the two reference rows 226 and 228 for sub-bit twists and the common plate line connection 370. Note that the reference cells are part of the basic structure of the memory core and not separate from the structure. This means that the plate pulse timing, pulse shape and voltage level are the same for the reference cell and the memory cell. The shared reference cell and memory cell plate line makes all plate related noise common mode. Finally the shared plate line eliminates the need to turn off the reference word line and memory cell word line before sensing and therefore improves the overall performance and reduces logic complexity compared to prior art devices.

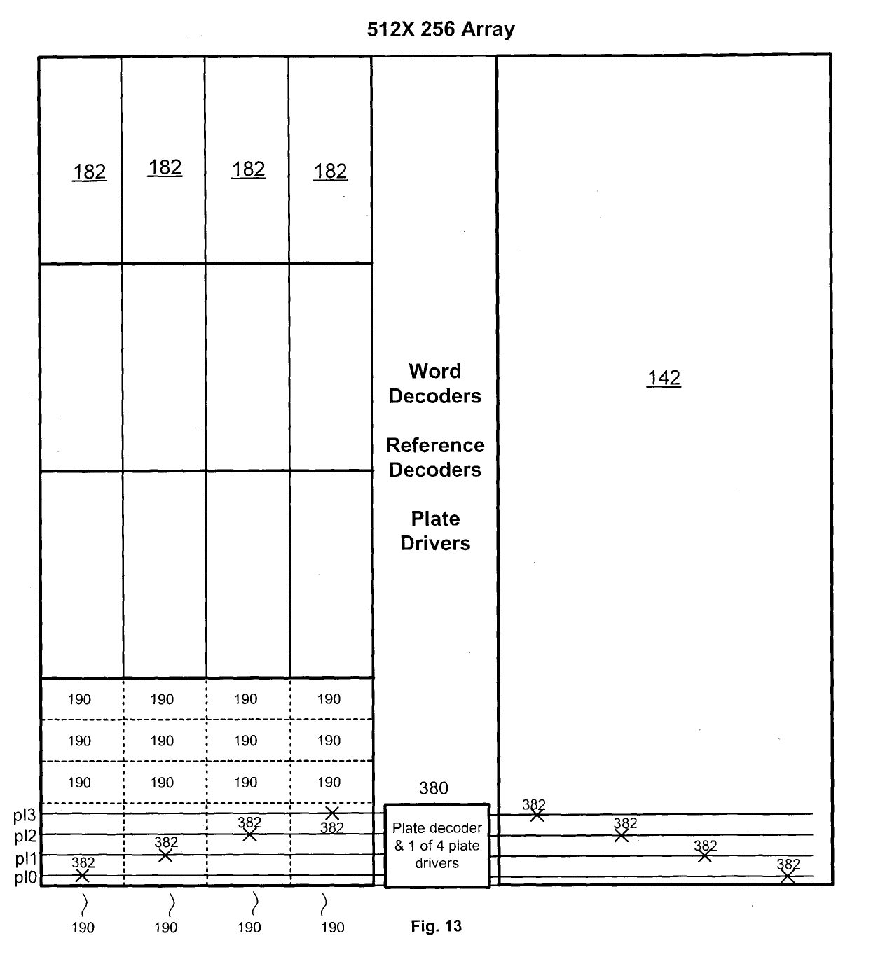

The four wires 230 are an illustration of plate clock connections, p10, p11, p12 & p13 that can be made for each basic memory block (See FIG. 13). Note that location of the bit twists 200 is between the parts 222, 224 of the basic memory cell. In one embodiment, the basic memory cell array contains a plurality of one ferroelectric capacitor one transistor memory cells. In another embodiment, the basic memory cell array contains a plurality of two ferroelectric capacitor two transistor memory cells. In another embodiment, the capacitor is not a ferroelectric capacitor. In another embodiment, control logic is capable of switching the memory cell from one capacitor one transistor to two capacitor two transistor memory cells and back. When the two capacitor two transistor memory cell is selected the amount of memory is reduced in half.

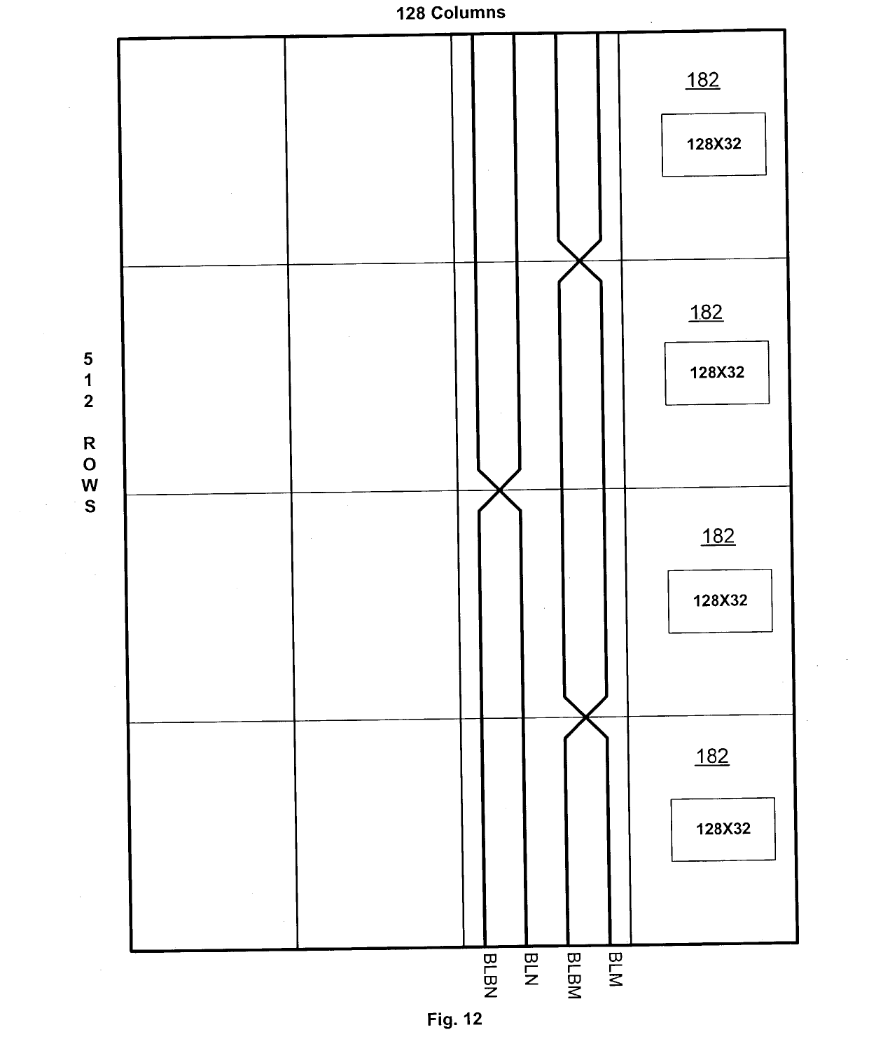

FIG. 12 is a more detailed schematic diagram of major bit twists in the standard memory array 142 in accordance with one embodiment of the invention. The diagram shows the standard memory array divided into 16 sub-memory cell arrays 182. Two bit line pairs are shown with bit twists alternating between the sub-memory cell arrays 182 at the quarter point and half point of the columns of the standard memory cell arrays 142 for bit line pair BLM and BLBM and the half point of the arrays for bit line pair BLN and BLBN. This alternating pattern of bit twists is true for all bit lines

FIG. 13 is a schematic diagram of a plurality of plate drivers in accordance with one embodiment of the invention. In this example one of the plate drivers 380 and its connections 382 are shown for a portion of a memory cell array 180 comprised of two standard memory cell arrays 142. Note that a single common plate line is associated with a basic memory cell array 190. This single common plate line is also the plate line for the reference cell(s) as is apparent from FIG. 11.

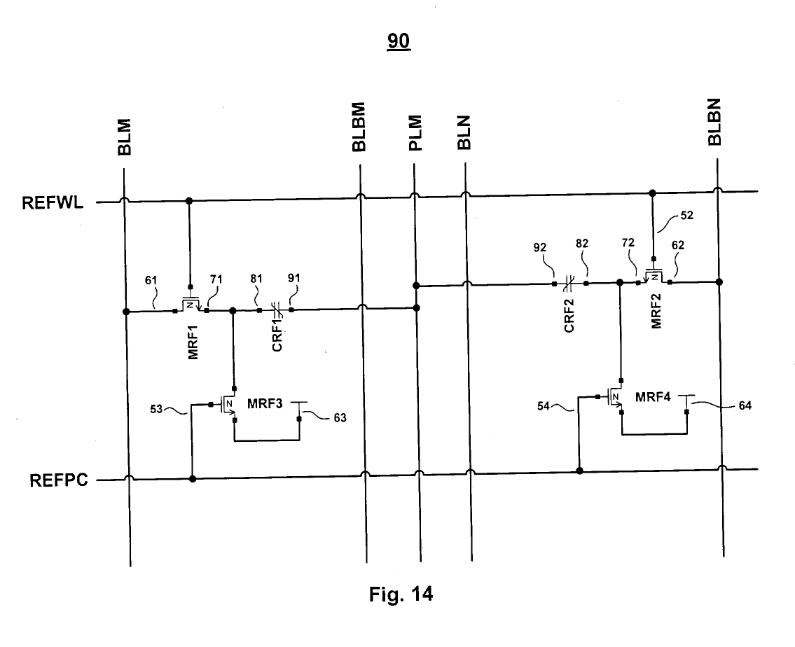

FIG. 14 is a schematic diagram 90 of the plurality of ferroelectric reference memory cells in accordance with one embodiment of the invention. In particular the FIG. 14 shows two ferroelectric reference memory cells. The reference memory cell 90 has a reference word line REFWL connected to a gate 51 of a first reference cell transistor MRF1. A bit line BLM is connected to a source 61 of the transistor M1. The bit line BLM runs perpendicular to the reference word lines REFWL and REFPC. A ferroelectric capacitor CRF1 has a first plate 81 connected to a drain 71 of the first reference transistor MRF1. A plate line PLM is connected to a second plate 91 of the ferroelectric capacitor CF1. The plate line PLM runs parallel to the bit line BLM. A second control wire REFPC is connected to the gate 53 of transistor MRF3 of a first reference cell. In one embodiment, the source 63 of transistor M3 is connected to ground potential. In another embodiment, the source of 63 of transistor M3 is connected to the power supply, VCC. In another embodiment, the source of 63 of transistor MRF3 is connected to a variable voltage source. A complementary bit line BLBM runs parallel to the bit line BLM. The reference word line REFWL connected to a gate 52 of a second reference cell transistor M2. A bit line BLBN is connected to a source 62 of the transistor M2. The bit line BLBN runs perpendicular to the reference word lines REFWL and REFPC. A ferroelectric capacitor CRF2 has a first plate 82 connected to a drain 72 of the second reference transistor MRF2. A plate line PLM is connected to a second plate 92 of the ferroelectric capacitor CRF2. A second control wire REFPC is connected to the gate 54 of transistor MRF4 of a second reference cell. In one embodiment, the source 64 of transistor MRF4 is connected to ground potential. In another embodiment, the source of 64 of transistor MRF4 is connected to the power supply, VCC. In another embodiment, the source of 64 of transistor MRF4 is connected to a variable voltage source. A complementary bit line BLN runs parallel to the bit line BLBN. In one embodiment of the current invention the plate line PLM is shared between the plates 91 and 92 of capacitors CRF1 and CRF2. In another embodiment there are separate plate lines PLM and PLN for capacitor plates 91 of CRF1 and 92 of CRF2 analogous to the separate plate lines of the memory cell of FIG. 6. The reference memory cell 90 has a topological and cross sectional layout analogous to the memory cells of FIGS. 1, 2, 3 and 4. The reference memory can also be configured with a shared plate line (See FIGS. 1,2 & 5) or a separate plate line pair bit line pair (See FIGS. 2,3 & 6). Note that the bit line BLM and the complementary bit line BLBM are at the same physical layer as the normal memory cell (See FIGS. 2 & 4). The bit line BLM is not over the plate line PLM but the complementary bit line BLBM is over the plate line PLM (, the top electrode 28 and/or the intermediate metal1 34 depending on the particular cross section (See FIGS. 1,2 and 3,4). The bit line BLBN is not over the plate line PLM but the complementary bit line BLN is over the plate line PLM (, the top electrode 28 and/or the intermediate metal1 34 depending on the particular cross section (See FIGS. 1,2 and 3,4).

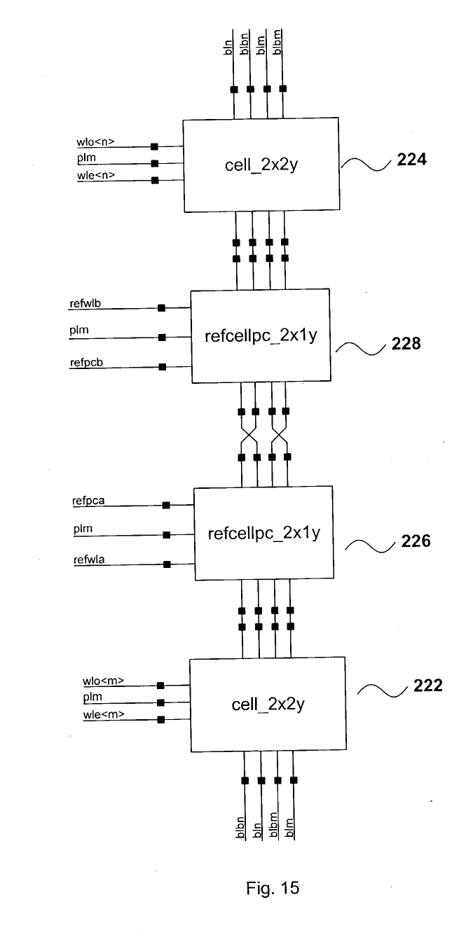

FIG. 15 is a schematic diagram of a portion of two columns of the memory core showing memory cells reference memory cells and sub-bit twists of the basic memory cell array in accordance with one embodiment of the invention. The corresponding topological configuration of the basic memory cell array 190 is shown in FIG. 11. The schematic diagram of FIG. 15 shows how the electrical connection relates to the physical diagram of FIG. 11. The twisting of the bit lines between reference rows shown in FIG. 15 allows the bit line topology for each bit line to be balanced in each basic memory cell array. FIGS. 11 and 15 along with the cross sectional and top views of the memory cells shown in FIGS. 1, 2, 3 and 4 show the relationship between electrical schematics and physical topologies to create balanced bit line pairs.

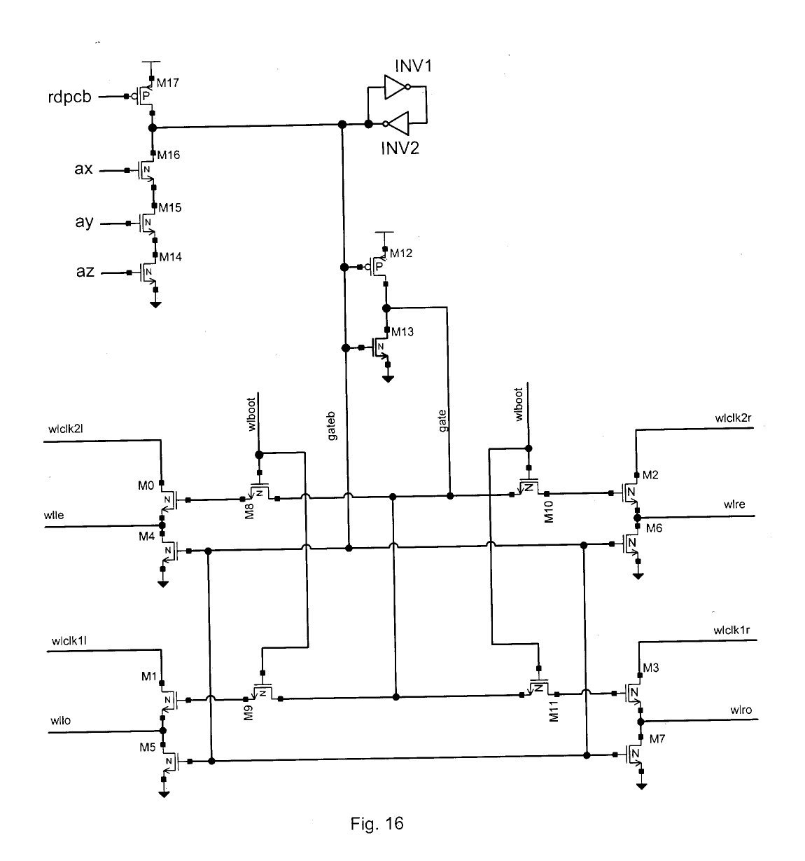

FIG. 16 is a schematic diagram of a word line driver and decoder circuitry in accordance with one embodiment of the invention. The circuitry is divided into two sections a decoder section comprised of devices M12 through M17 and two CMOS inverter circuits INV1 and INV2 and a driver section comprised of devices M0 through M11.

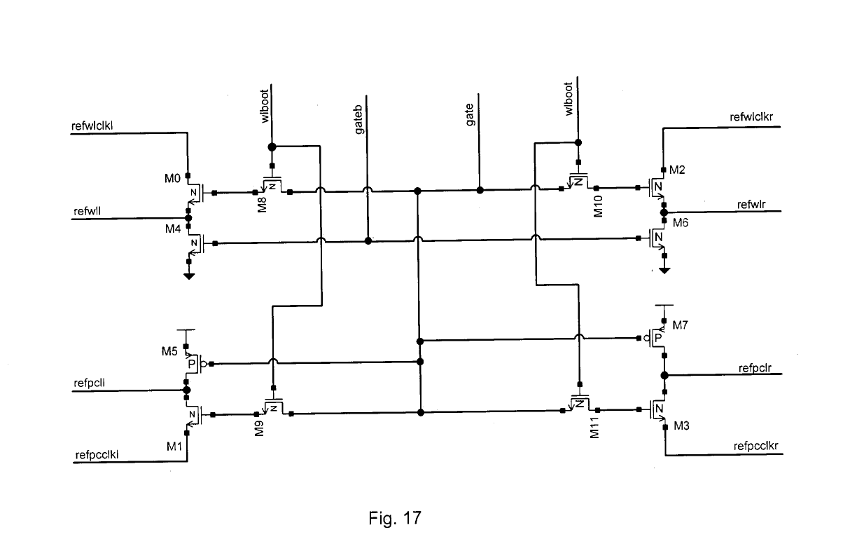

FIG. 17 is a schematic diagram of a reference word line driver and reference word line precharge driver circuit in accordance with one embodiment of the invention. The schematic diagram of the reference word line driver and reference precharged driver of FIG. 17 is conformed both physically and electrical to that of the word line driver.

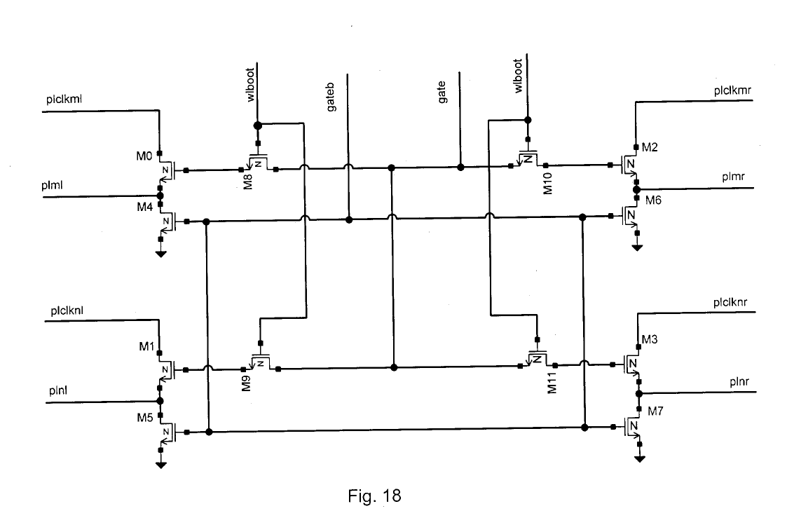

FIG. 18 is a schematic diagram of a plate line driver circuit in accordance with one embodiment of the invention. The schematic diagram of the plate line driver of FIG. 18 is conformed both physically and electrical to that of the word line driver.

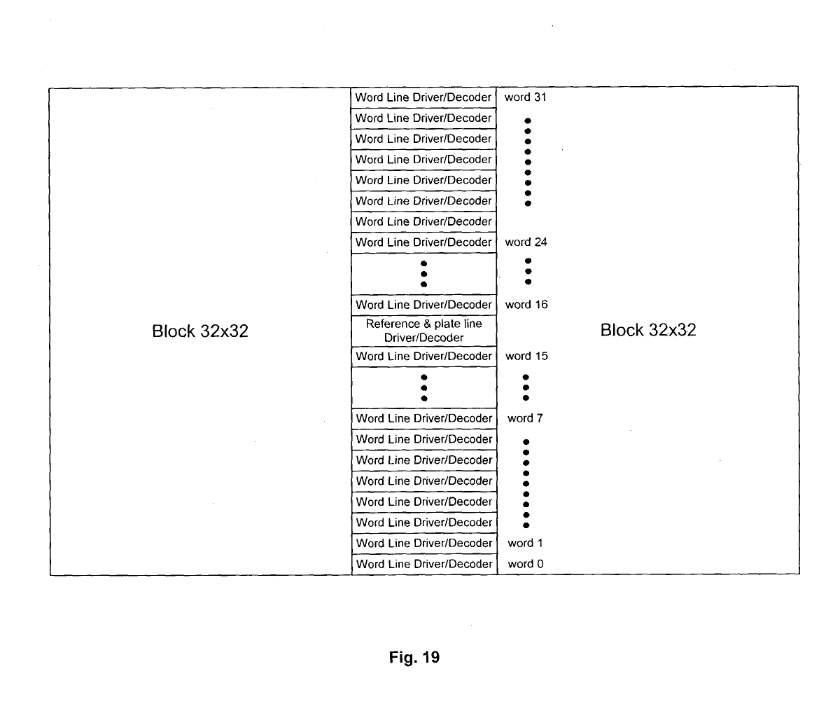

FIG. 19 is a detailed block diagram of the basic memory cell array showing the location of the word line, reference word line and plate line driver circuitry corresponding to FIGS. 16, 17 and 18 and 20. This block diagram of FIG. 19 shows how each of the drivers; word line, reference word line, reference precharge and plate driver are physically related. Each driver because of the common conformation of the circuit elements allows them to share the connections of clocks, address wires and power supply connections in the physical space between arrays. This greatly reduces the overhead normally associated with the plate driver circuitry and allows for a more efficient memory layout.

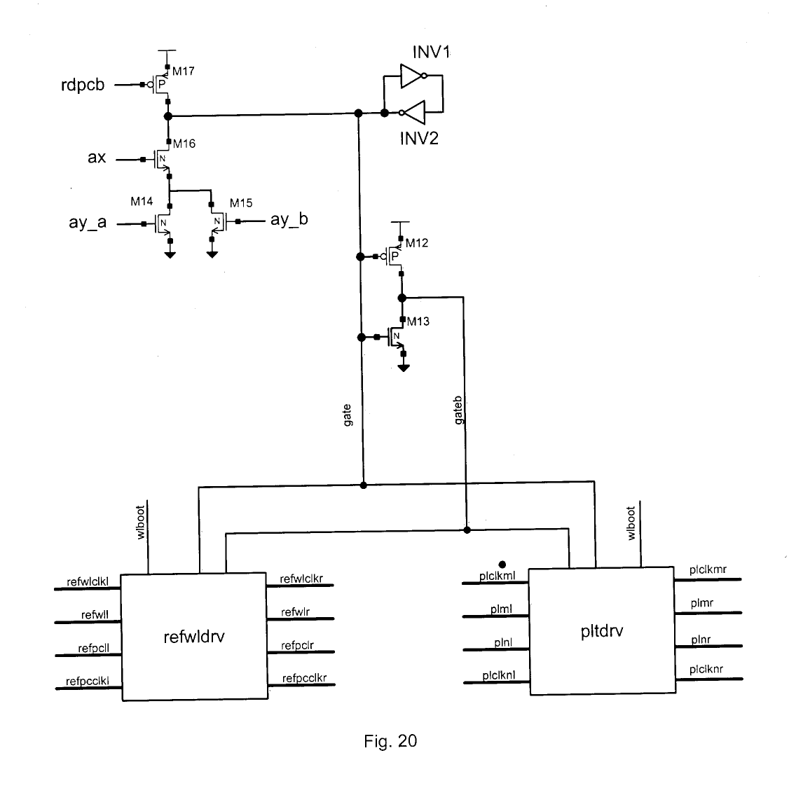

FIG. 20 is a detailed schematic diagram showing the combination of the decoding circuitry and driver circuitry for the reference word line, reference precharge, and plate line. FIG. 20 shows how the reference word line driver, reference precharge driver and plate drivers are connected together to conform to the same electrical and topological form as the word line driver and decoder of FIG. 16. FIG. 20 is comprised of two sections similar to the word line decoder of FIG. 16, a decoder section and driver sections. Devices M12 through M17 and inverters INV1 and INV2 form the decoder section and the blocks labeled refwldrv and pltdrv are the driver section. The block refwldrv contains the driver circuitry for the reference word line and reference precharge line and is shown in more detail in FIG. 17. The block pltdrv contains the driver circuitry for the plate lines and is shown in more detail in FIG. 18.

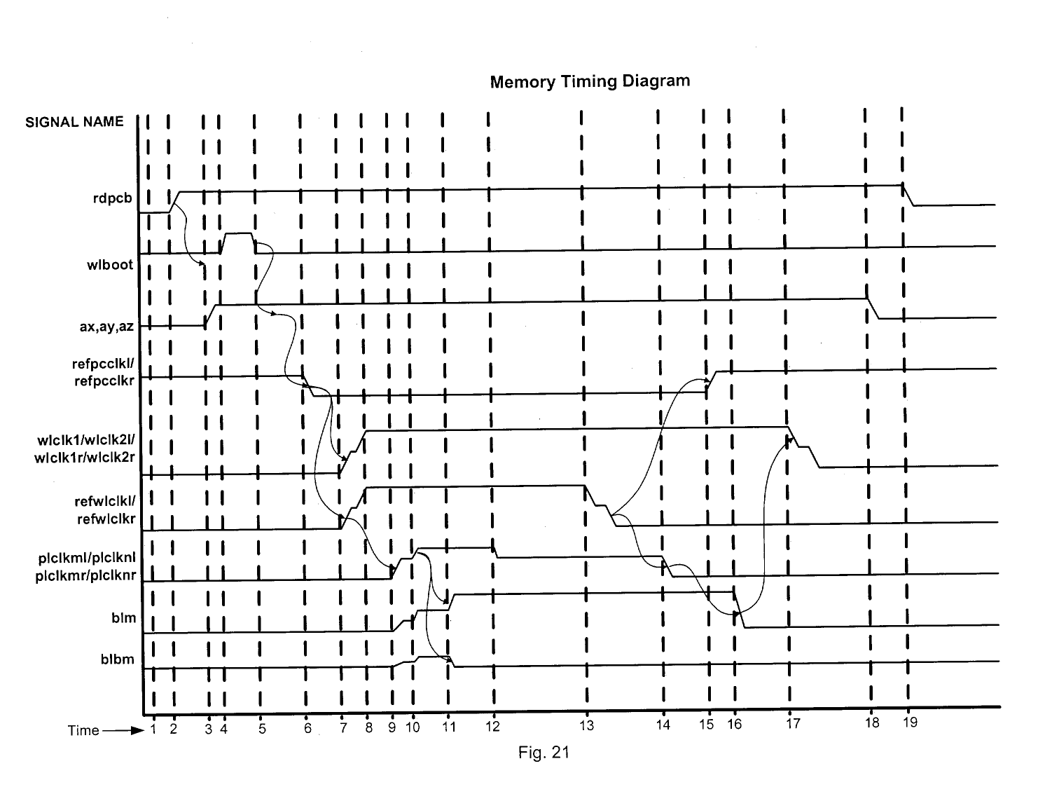

FIG. 21 is a diagram showing the timing relationships between the clocks necessary to operate the basic memory cell array, the word line driver and decoder, the reference cell driver and decoder, the reference precharge driver and decoder and the plate line driver and decoder.

### DETAILED DESCRIPTION OF THE OPERATION OF THE BASIC MEMORY CELL ARRAY

The electrical operation of the 1T/1C memory cell of FIG. 5 and the reference cell of FIG. 14 utilized to form the basic memory cell array are described by the timing diagram of FIG. 21. The electrical operation of the word line decoder and driver of FIG. 16 and the reference word line, reference precharge line and plate line drivers and decoders of FIG. 20 used to access the basic memory cell array are also described by the timing of FIG. 21. Various relative time points are indicated by dashed vertical lines numbered from 1 to 15. The numbers indicate relative increasing time within a memory operation cycle. The arrows on the figure indicate the signal dependencies of each timing pulse.

Referring to the timing diagram of FIG. 21 at time “1” all signals are initialized at ground except for the signals labeled refpcclkl/refpcclkr and wlboot. The signals labeled refpcclkl/refpcclkr and wlboot are initialized to the high power supply level, VCC. FIG. 5 and FIG. 14 show representative bit lines labeled BLM, BLBM, BLN and BLBN. All bit lines in the basic memory cell array are initialized to ground through appropriate precharge or initialization circuitry.

The signal RDPCB from the timing diagram initializes the decoders and drivers of FIGS. 16, 17, 18 and 20. The signal RDPCB is connected to the gate of a P-channel device, M17 in the word line decoder of FIG. 16 and a similar P-channel device also labeled M17 in FIG. 20. These P-channel devices along with devices labeled M12 and M13 in FIGS. 16 and 20 initialize the signals labeled “gateb” in FIGS. 16, 17, 18 and 20 to a VCC power supply level and the signal labeled “gate” of FIGS. 16, 17, 18 and 20 to a ground level. The address signals labeled ax, ay and az of FIGS. 16 and 20 are supplied from externally buffered address signals are initially set at ground. The control signal labeled “gateb” of FIG. 16 activates the gates of M4, M5, M6 and M7 of the word line driver to a high level pre-charging word lines wllo, wlle, wlro and wlre to ground. The control signal labeled “gate” in FIG. 16 is connected to transistors M0, M1, M2 and M3 through devices M8, M9, M10, M11 respectively and maintains devices M0, M1, M2 and M3 in the “off” condition. Similarly in FIG. 17 the signal labeled “gateb” also initializes the gates of M4 and M6 to a high level and precharges the reference word lines, refwll and refw1r to ground. The signal labeled “gate” in FIG. 17 is connected to transistors M0, M1, M2 and M3 through devices M8, M9, M10, M11 and maintains devices M0, M1, M2 and M3 in the “off” condition. In addition the control signal “gate” of FIG. 17 is also connected to P-channel devices M5 and M7 and precharges the reference precharge lines, refpcll and refpc1r at the VCC power supply level. Note that in the reference word line driver schematic of FIG. 17 devices M5 and M7 are P-channel devices and in FIG. 16 these devices are N-channel. This device polarity reversal between the word line driver circuitry of FIG. 16 and the reference word line driver circuitry of FIG. 17 allows the circuitry to easily share the same topological form but inverts the polarity of the initialization signals for word lines and reference precharge lines. The driver circuitry for the plate line of FIG. 18 is the same circuit as used for the word line driver portion of FIG. 16. The control signals “gate” and “gateb” of FIG. 17 operate in an identical manner to the signals in FIG. 16 and initialize the plate line signals plml, plnl, plmr and plnr to ground.

The initial conditions for the memory cell, FIG. 5 are determined by the word line, reference word line and plate line circuits of FIGS. 16, 17, 18 and 20. For the memory cell of FIG. 5 the word lines wle and wlo are in the off or ground condition, the plate line plm is in the off condition and the bit lines, BLM, BLBM, BLN and BLBN as previously mentioned are also at ground. FIG. 5 shows four memory cells. The internal node of each memory cell is the shared connection between the transistor and the ferroelectric capacitor. For example for one of the memory cells the internal node is the shared connection between M3 and CF3 a second internal node is the connection shared my M1 and CF1 and so forth. The initial condition for the internal nodes for all memory cells is ground.

For the reference cell for FIG. 14 the reference precharge line, refpc is at power supply level, VCC level, the reference word line, refwl is at a ground level. The bit lines, BLM, BLBM, BLN and BLBN and the plate line plm of the reference cell are the same bit lines and plate lines as the memory cell as indicated by the portion of the array interconnection shown in FIG. 15. FIG. 14 shows two reference cells with two internal nodes. The first internal node is defined as the common point between M1, M3 and CF1 and a second internal node is defined as the common connection between devices M2, M4 and CF2. The internal nodes are both initialized two a power supply level, VCC minus one N-channel device threshold or VCC-Vtn, where Vtn is the N-channel threshold. Under these conditions the ferroelectric devices CF1 and CF2 of FIG. 14 are polarized in a plus minus direction from the internal node to the plate line plm.

At time T2 the signal RDPC is driven from ground to a power supply level and each of the decoders for word line, reference word line-plate line are latched in the initialized state via cross coupled inverters INV1 and INV2 in FIGS. 16 ands 20. At time T3 a sequence of addresses signals are supplied to the memory array. This address sequence uniquely selects only 1 word line decoder, FIG. 16 and one reference word line-plate line decoder, FIG. 20. For the decoder to be selected all address, ax, ay and az must be in a high condition. The logic states for the signals “gateb” and “gate” are switched with “gateb” driven to ground and “gate” driven to the power supply level. In FIG. 16 the activation of the “gate” signal enables devices M0, M1, M2 and M3 through transistors M8, M9, M10 and M11 respectively connecting the word line clocks wlclk1l, wlclk2l, wlclk1r and wlclk2r to word lines wllo, wlle, wlro and wlre respectively. In a similar manner the reference clocks, refwlclkl and refwlclkr are connected to the reference word lines refwll and refill, the reference precharge clocks, refpcclkl and refpcclkr are connected to the reference precharge lines, refpcl and refpcr and the plate clocks, plclkml, plclknl, plclkmr and plclknr are connected to there respective plate lines plml, plnl, plmr and plnr. Between times T4 and T5 the signal wlboot of FIGS. 16, 17, 18, and 20 is raised above the power supply level to insure the gates of devices M0, M2, M2 and M3 are initialized at full supply voltage to improve the low voltage operating margin. At time T6 the reference precharge clocks refpcclkl and refpcclkr are driven from the power supply level to ground. This also sets the reference precharge lines refpcll and refpc1r to ground through devices M1 and M3 of FIG. 17 isolating the internal reference cell nodes.

At a time prior to T7 the precharge circuitry used to initialize the bit lines is deactivated and the bit lines are left floating at a ground level.

At time T7 one of the four word line clocks and one of the reference word line clocks is activated and driven either to a power supply level or a boosted or above power supply level. The boosting is indicated at time T8 fro both the word line and reference word line clocks. The high voltage level is determined by the margin requirements of the ferroelectric material and the specific design requirements of the memory. FIG. 15 shows that there are two sets of reference word lines in a basic memory cell array. Referring to FIG. 15, if a word line is selected in the lower half of the basic memory cell array, wlo<m> or wle<m> then the reference word line in the upper half is selected, refwlb. If a word line is selected in the upper half of the basic memory cell array, wlo<n> or wle<n> then the reference word line in the lower half is selected, refwla. This selection of a memory cell on one side of the sub-bit twists in the basic memory cell and a reference word line on the other side of the sub-bit twists in a basic memory cell array connects a memory cell to a bit line BLM or BLBN and a reference cell to the opposite bit line BLBM or BLN respectively. In the basic memory cell array on reference word line is shared by 16 word lines in each half of the basic memory cell array.

At time T9 a single plate clock is selected and is driven to a high level. There are multiple plate clocks in a memory array as indicated in FIG. 13. The plate line drivers share the same decoding as the reference word lines as shown in FIG. 20. The addressing used to select the reference word line-plate line decoders, FIG. 20 is a sub-set of the addresses used to select a particular word line. Therefore the selection of the word line controls which reference word line is activated in a particular basic memory cell array as indicated in FIG. 13. There are multiple plate clocks within a reference word line-plate line decoder. An example is shown in FIG. 13 of four plate clocks on the left and right half of the arrays, 142. The selection of one of the four plate clocks is further determined by which column group, 190 is being read or written. For the example shown in FIG. 13, the word line, reference word line and reference precharge line are common for all four blocks on either side of the 512×256 array. Therefore the plate line clock selection determines which portion of the array is read or written. In this example only one basic memory cell array of 32 word lines, two reference word lines and a common plate clock is activated. For the un-activated plate blocks in the column direction indicated by blocks 182 of FIG. 13 the bit line precharge circuitry remains active and the bit lines in these column blocks remain at a precharge level of ground.

The plate clock is driven either to a power supply level or a boosted level, time T10 above the power supply that is determined by the requirements of the ferroelectric material and margin requirements of the memory. The unique common structure of the word line, reference word line and plate line driver circuitry allows the clock levels for the word line clocks, reference word line clocks and plate line clocks to be easily driven above the power supply through a common bootstrapping or high voltage circuit since all devices in the clock path are N-channel

A further advantage of this common structure allows the clock signals to be shared between pairs of drivers for each of the word line, reference word line and plate line driver circuits creating a physically compact and efficient layout reducing the overall size of the memory.

Referring to FIG. 5 when a word line is activated at time T7 the memory cell is connected to the bit line via devices M1 or M2 or devices M3 or M3 depending on which word line was selected. FIG. 5 shows four memory cells and two pairs of bit lines. If word line w/e is activated ferroelectric capacitor CF1 is connected to BLM and ferroelectric capacitor CF2 is connected to BLBN. Also at time T7 the reference line was activated. If the memory cell activated was in the lower half of the basic memory, 222 of FIG. 15, wle<m> then the upper reference word line of a basic memory cell is activated, refwlb of block 228 of FIG. 15. Activation of the reference word line, refwlb, FIG. 15 connects CRF1 to BLBM and CRF2 to BLN. FIG. 14 shows the capacitors of the reference cells, CRF1 and CRF2 connected through devices M1 and M2 respectively to bit lines BLM and BLBN however the bit twists of the basic memory cell array shown in FIG. 15 reverses the wires BLM with BLBM and BLBN with BLN of the reference cell. Therefore bit line pairs BLM and BLBM has a memory cell connected to bit line BLM and a reference memory cell connected to bit line BLBM and bit line pair BLN and BLBN has a memory cell connected to bit line BLBN and a reference memory cell connected to bit line BLN.

The memory cells had an initial condition of ground and also all bit lines initial conditions were also ground therefore no change of voltage takes place on the bit lines connected to the memory cells. The reference cells however had an initial condition of VCC-Vtn, therefore when the reference word line is activated the charge stored on the ferroelectric capacitors CRF1 and CRF2 is shared with there respective bit lines. The amount of voltage developed on the bit lines connected to the reference cells depends on the size of the reference capacitor, the value of the bit line capacitance and on the initial voltage level of the reference cell. The connection of the reference cells to the bit lines results in a sharing of the charge on the ferroelectric capacitor with the bit lines and the net voltage produce is determined by the ratio of the bit lien capacitance and the equivalent ferroelectric capacitance. This charge sharing results in no switching of the ferroelectric polarity since the voltage across the ferroelectric capacitor remains plus to minus from the internal node of the ferroelectric cell to the plate line. Therefore only linear or non-switching charge is shared with the bit lines connected to the reference cells.

At time T9 the plate line is activate and driven to a high level power supply level or a boosted level above the power supply. As the plate line begins to rise the voltage on the plate line will exceed the voltage on the internal node of the memory cells. When this voltage exceeds the coercive or switching voltage of the ferroelectric memory cells the polarization state of the ferroelectric memory cell will be read. If “1” polarization data state was stored in the ferroelectric memory cell switching will occur and a large amount of charge will be transferred to the bit line resulting in a voltage on the bit line. If a “0” polarization data state was stored in the ferroelectric memory cell no switching will occur and a small amount of charge will be transferred to the bit line.

The plate line for the memory cells and the reference memory cells is shared as is indicated in FIGS. 5, 11, 14 for the basic memory cell array. When the plate line rises at time T9 and the polarization state of the memory cells is transferred to the bit lines the reference cells also transfer charge to the bit lines connected to the reference memory cells through ferroelectric capacitors CRF1 and CRF2. The initial conditions of the ferroelectric capacitors in the reference cells was plus to minus from the internal node to the plate line. As the plate line rises at time T9 the plate line voltage will exceed the voltage of the internal nodes of the reference memory cells. This will cause a polarity reversal in all reference memory cells activated and switched charge will be transferred from the reference memory cell to the bit lines connected to the reference memory cells. Therefore the resultant voltage on the bit lines connected to the reference memory cells will be a combination of linear, non-switching charge and switched charge. The value of the charge transferred to the bit lines connect to the reference word lines and the resultant bit line voltage is determined by the size of the reference cell, the initial voltage condition of the reference cell prior to the reference word line activation, the ratio of the bit line capacitance to the reference cell equivalent capacitance and the voltage applied of the plate line. These values are adjusted to position the resultant voltage between the “1” data and “0” data state of the memory cell. This combination of linear non-switching terms and switching terms for the reference cells along with the adjustability of the initial condition voltage of the reference cell and the value of the plate pulse create very stable reference level. Sharing the plate line between the reference cells allows for reduced noise and common mode operation and a distributed localized reference cell in each basic memory cell array for further stability. In addition utilizing only N-channel devices in the reference cell reduces the size and complexity of the physical layout of the memory cell.

At time T11 a suitable latch or sense amplifier connected to the bit line pairs is activated and the information read from the memory cells is amplified to full logic levels.

At time T12 if the plate line was driven to a level above the power supply the plate voltage is reduced to power supply level. At time T13 the reference word lines are reset to ground to isolated the reference cells from the bit lines. At time T14 the plate line is reset to ground finishing the restore operation of the ferroelectric memory data. At time T15 the reference memory cells are reinitialized to VCC-Vtn.

At time T16 the sense amplifiers are disabled and the bit lines are reinitialized to ground resetting the internal node of the memory cells to ground. At time T17 the word line clocks and word lines are reset to ground and at times T18 and T19 the remaining signals ax, ay and az and RDPCB are reset to ground reinitializing the decoders and drivers to there original conditions.

All nodes are then at the starting conditions of time T1 and a memory read cycle has been completed. If the cycle were a write cycle then after the latching of data at time T11 and prior to the plate line being driven to ground at time T14 new data would be written on to the bit lines through appropriate column selection and driver circuitry.

Thus there has been described a memory core and memory core architecture that has the following features. The ferroelectric memory cell requires less space than previous designs. The ferroelectric memory cell has the common plate line running parallel to the bit lines. The ferroelectric memory architecture combines reference cells with array cells in a local sub-array and utilizes a common plate line for both reference cells and memory cells. The ferroelectric memory cell architecture combines the plate line decoder and driver in the same physical space as the word line decoder driver and the reference word line decoder and driver. The ferroelectric memory architecture uses a similar circuit configuration for the word line, reference word line and plate line decoder and driver circuitry. In addition these improvements and modifications create a ferroelectric memory that uses less power than previous designs. Note that while the invention has been described with respect to ferroelectric memories, some of the architecture features are applicable to other types of memories. For instance, the ability to switch between a one transistor one capacitor configuration and a two transistor two capacitor configuration.

While the invention has been described in conjunction with specific embodiments thereof, it is evident that many alterations, modifications, and variations will be apparent to those skilled in the art in light of the foregoing description. For instance, the size of the memory cores shown in the drawings are for illustration purposes only and are not intended to limit the possible memory sizes. In addition, the architecture of the memory core is applicable to many memory systems and is not limited to ferroelectric memories. Accordingly, it is intended to embrace all such alterations, modifications, and variations in the appended claims.

What is claimed is:

1. A ferroelectric memory cell, comprising:
a word line connected to a gate of a transistor;
a ferroelectric capacitor having a first plate connected to a drain of the transistor;
a bit line connected to a source of the transistor and running perpendicular to the word line; and
a plate line forming a second plate of the ferroelectric capacitor, the plate line running parallel to the bit line.

2. The memory cell of claim 1, further including a complementary bit line electrically isolated from the ferroelectric capacitor running parallel to the bit line.

3. The memory cell of claim 2, wherein the complementary bit line and the bit line are on the same physical level.

4. The memory cell of claim 1, wherein the bit line is not over the plate line.

5. The memory cell of claim 2, wherein the complementary bit line is over the plate line.

6. The memory cell of claim 1, wherein the bit line is connected via a first contact and a metal layer and a second contact to the source of the transistor.

7. The memory cell of claim 1 wherein the second plate of the ferroelectric capacitor is formed by the plate line.

8. The memory cell of claim 1, wherein an “X” pitch is wider a “Y” pitch of the memory cell.

9. A ferroelectric memory cell, comprising:
a word line connected to a first gate of a first transistor and a second gate of a second transistor;
a first ferroelectric capacitor having a first top electrode connected to a first drain of the first transistor;
a second ferroelectric capacitor having a second top electrode connected to a second drain of the second transistor; and
a plate line connected to a first bottom electrode of the first transistor and a second bottom electrode of the second transistor.

10. The memory cell of claim 9, wherein the plate line is perpendicular to the word line.

11. The memory cell of claim 9, further including a first bit line connected to a first source of the first transistor and a second bit line connected to a second source of the second transistor.

12. The memory cell of claim 11, further including a first complementary bit line running parallel to the first bit line and a second complementary bit line running parallel to the second bit line.

13. The memory cell of claim 12, wherein the first complementary bit line and the second complementary bit line are symmetrically placed about a centerline of the plate line.

14. The memory cell of claim 9, wherein the first top electrode and the second top electrode are placed symmetrically about a centerline of the plate line.

15. The memory cell of claim 13, wherein the first top electrode is symmetrically placed relative to a centerline of the first complementary bit line.

16. A ferroelectric memory cell, comprising:
a first bit line;
a first transistor having a first source connected to the first bit line, the first transistor symmetrically placed under a centerline of the first bit line;
a ferroelectric capacitor having a top electrode connected to a first drain of the first transistor;
a plate line forming a bottom electrode of the ferroelectric capacitor, the plate line running parallel to the first bit line; and
a first complementary bit line having a centerline, the top electrode and the bottom electrode symmetrically placed under the centerline of the first complementary bit line.

17. The memory cell of claim 16, further including a second transistor and a second ferroelectric capacitor, wherein the second capacitor and the second ferroelectric capacitor are a mirror image of the first transistor and the ferroelectric capacitor.

18. The memory cell of claim 17, further including a word line connected to a first gate of the first transistor and a second gate of the second transistor.

19. The memory cell of claim 18, further including a second complementary bit line that is a mirror image of the first complementary bit line.

20. The memory cell of claim 19, wherein the mirror image has an image line that is concurrent with an edge of the plate line.

21. A ferroelectric memory core comprising:
a first standard memory cell array;
a second standard memory cell array adjacent to the first standard memory cell array;
a word line decoder and driver between the first standard memory cell array and the second standard memory cell array; and
a sense amplifier on an outside edge of the first standard memory cell array.

22. The ferroelectric memory core of claim 21, further including a plate line decoder and driver between the first standard memory cell array and the second standard memory cell array.

23. The ferroelectric memory core of claim 21, further including a reference word line decoder and driver between the first standard memory cell array and the second standard memory cell array.

24. The ferroelectric memory core of claim 21, wherein the standard memory cell array includes a plurality of basic memory cell arrays.

25. The ferroelectric memory core of claim 24, wherein the basic memory cell array comprises a pair of sub-basic memory cell arrays with a reference cell between the pair of sub-basic memory cell arrays.

26. The ferroelectric memory core of claim 25, further including a bit line twist near the reference cell.

27. The ferroelectric memory core of claim 24, wherein a single common plate line is associated with one of the plurality of basic memory cell arrays.

28. The ferroelectric memory core of claim 27, wherein the single common plate line is also the plate line for the reference cell.

29. The ferroelectric memory of claim 21, wherein a standard memory cell array of the first pair of standard memory cell arrays has a plurality of memory cells, each of the plurality of memory cells has a single ferroelectric capacitor.

30. The ferroelectric memory of claim 29, wherein each of the plurality of memory cells has a single transistor.

31. The ferroelectric memory of claim 28, wherein each of the plurality of memory cells has a bit line that runs perpendicular to a word line.

32. A memory core comprising:
a first standard memory cell array;
a second standard memory cell array that is a mirror image of the first standard memory cell array along a first mirror line; and
a word line decoder between the first standard memory and the second standard memory.

33. The memory core of claim 32, further including:
a third standard memory cell array that is a mirror image of the first standard memory along a second mirror line;
a column select circuitry between the first standard memory cell array and the third standard memory cell array.

34. The memory core of claim 33, wherein the first standard memory cell array contains a plurality of one ferroelectric capacitor, one transistor memory cells.

35. The memory core of claim 32, further including a plate line driver between the first standard memory cell array and the second standard memory cell array.

36. The memory core of claim 32, further including a reference cell decoder between the first standard memory cell array and the second standard memory cell array.

37. The memory core of claim 32, wherein the standard memory cell array includes a basic memory cell array having a single common plate line.

38. The memory core of claim 37, wherein the basic memory cell array has a reference cell along a basic memory mirror image line.
